(19) United States
(12) Patent Application Publication
(10) Pub. No.: US 2024/0170284 A1
(43) Pub. Date: May 23, 2024

(54) METHOD FOR PRODUCING A SILICON CARBIDE-BASED SEMICONDUCTOR STRUCTURE AND INTERMEDIATE COMPOSITE STRUCTURE

(71) Applicant: Soitec, BERNIN (FR)

(72) Inventors: Gweltaz Gaudin, Bernin (FR); Christophe Maleville, Bernin (FR); lonut Radu, Bernin (FR); Hugo Biard, Bernin (FR)

(21) Appl. No.: 18/550,044

(22) PCT Filed: Mar. 3, 2022
(86) PCT No.: PCT/FR2022/050379

§ 371 Date: Sep. 11, 2023

(30) Foreign Application Priority Data
Mar. 9, 2021 (FR) FR2102306

(51) Int. Cl. H01L 21/02; C23C 16/02; C23C 16/32; C23C 16/56; H01L 21/762

(52) U.S. Cl. CPC H01L 21/02529; C23C 16/0227; C23C 16/325; C23C 16/56; H01L 21/02378; H01L 21/02447; H01L 21/76254

(57) ABSTRACT

A method for producing a semiconductor structure, comprises: a) providing a temporary substrate made of graphite having a grain size of between 4 microns and 35 microns, a porosity of between 6 and 17%, and a coefficient of thermal expansion of between 4×10-6/° C. and 5×10-6/° C.; b) depositing, on a front face of the temporary substrate, a carrier layer made of polycrystalline silicon carbide having a thickness of between 10 microns and 200 microns, c) transferring a working layer made of monocrystalline silicon carbide to the carrier layer to form a composite structure, the transfer implementing bonding by molecular adhesion, d) forming an active layer on the working layer, e) and removing the temporary substrate to form the semiconductor structure, the structure including the active layer, the working layer and the carrier layer. A composite structure is obtained in an intermediate step of the production method.

### CROSS-REFERENCE TO RELATED APPLICATIONS

This application is a national phase entry under 35 U.S.C. § 371 of International Patent Application PCT/FR2022/050379, filed Mar. 3, 2022, designating the United States of America and published as International Patent Publication WO 2022/189732 A1 on Sep. 15, 2022, which claims the benefit under Article 8 of the Patent Cooperation Treaty of French Patent Application Serial No. FR2102306, filed Mar. 9, 2021.

### TECHNICAL FIELD

The present disclosure relates to the field of semiconductor materials for microelectronic components. In particular, it relates to a method for producing a semiconductor structure comprising an active layer made of high-quality monocrystalline silicon carbide comprising or intended to accommodate electronic components, the active layer being arranged on a carrier layer made of polycrystalline silicon carbide. The present disclosure also relates to an intermediate composite structure obtained in the method.

### BACKGROUND

Interest in silicon carbide (SiC) has increased considerably over the last few years because this semiconductor material can increase the energy handling capacity. SiC is increasingly widely used for producing innovative power devices to meet the needs of rising fields in electronics, such as electric vehicles, in particular.

Power devices and integrated power supply systems based on monocrystalline silicon carbide are able to manage a much higher power density in comparison with their conventional homologues made of silicon, and do so with active regions of smaller size. To further reduce the dimensions of power devices on SiC, it is advantageous to produce vertical instead of lateral components. To that end, vertical electrical conduction between an electrode arranged on the front face of the assembly of components and an electrode arranged on the back face must be allowed by the assembly.

Bulk substrates made of monocrystalline SiC intended for the microelectronics industry nevertheless remain expensive and difficult to source in large sizes. Furthermore, when it is produced on a bulk substrate, the assembly of electronic components often requires the back face of the substrate to be thin, typically around 100 microns, in order to reduce the vertical electrical resistivity and/or to meet space and miniaturization specifications.

It is therefore advantageous to use solutions for transferring thin layers in order to produce composite structures typically comprising a thin layer made of monocrystalline SiC on a lower cost carrier substrate, with the thin layer being used to form the electronic components. One well-known solution for transferring thin layers is the Smart Cut™ method, based on implanting light ions and joining by direct bonding. Such a method makes it possible, for example, to produce a composite structure comprising a thin layer made of monocrystalline SiC (c-SiC), taken from a donor substrate made of c-SiC, in direct contact with a carrier substrate made of polycrystalline SiC (p-SiC), and allowing vertical electrical conduction. The carrier substrate, which must be thick enough to be compatible with the formation of the components, is finally thinned to obtain the assembly of electronic components ready to be integrated. Even if the carrier substrate is of lower quality, the thinning steps and the loss of material are still cost contributors, which are preferably to be eliminated.

U.S. Pat. No. 8,436,363 is also known, which describes a method for producing a composite structure comprising a thin layer made of c-SiC arranged on a metal carrier substrate, the coefficient of thermal expansion of which matches that of the thin layer. This production method comprises the following steps:
forming a buried weakened plane in a donor substrate made of c-SiC, defining a thin layer between the buried weakened plane and a front surface of the donor substrate,
depositing a metal layer, for example, made of tungsten or of molybdenum, on the front surface of the donor substrate in order to form the carrier substrate with sufficient thickness to act as a stiffener,
separating, along the buried weakened plane, in order to form, on the one hand, the composite structure comprising the metal carrier substrate and the thin layer made of c-SiC and, on the other hand, the rest of the donor substrate made of c-SiC.

The drawback of this approach is that a metal carrier substrate is not always compatible with production lines for electronic components. The carrier substrate may also need to be thinned, depending on the application.

### BRIEF SUMMARY

The present disclosure relates to an alternative solution to those of the prior art, and aims to remedy all or some of the aforementioned drawbacks. In particular, it relates to a method for producing a semiconductor structure for electronic components, advantageously vertical components, produced on and/or in an active layer made of high-quality monocrystalline silicon carbide, which is arranged on a carrier layer made of polycrystalline silicon carbide. The present disclosure also relates to a composite structure obtained in an intermediate step of the production method.

The present disclosure relates to a method for producing a semiconductor structure, comprising:
a) a step of providing a temporary substrate made of graphite having a grain size of between 4 microns and 35 microns, a porosity of between 6 and 17%, and a coefficient of thermal expansion of between 4.10-6/° ° C. and 5.10-6/° C.;
b) a step of depositing, directly on a front face of the temporary substrate, a carrier layer made of polycrystalline silicon carbide having a thickness of between 10 microns and 200 microns,
c) a step of transferring a working layer made of monocrystalline silicon carbide to the carrier layer, directly or via an intermediate layer, to form a composite structure, the transfer implementing bonding by molecular adhesion,
d) a step of forming an active layer on the working layer, and
e) a step of removing the temporary substrate to form the semiconductor structure, the structure including the active layer, the working layer and the carrier layer.

According to other advantageous and non-limiting features of the present disclosure, taken individually or in any technically feasible combination:
the deposition of step b) is also performed on a back face of the temporary substrate to form a second carrier layer, and/or on a peripheral edge of the substrate;
transfer step c) comprises:

introducing light species into the donor substrate made of monocrystalline silicon carbide to form a buried weakened plane defining, with a front face of the donor substrate, the working layer,
joining the front face of the donor substrate to the carrier layer, directly or via an intermediate layer, by means of bonding by molecular adhesion, and
separating, along the buried weakened plane, to transfer the working layer to the carrier layer;
   the intermediate layer is formed of tungsten, silicon, silicon carbide or other conductive or semiconductor materials;
   separation occurs in a heat treatment at a temperature of between 800° ° C. and 1200° C.;
   step d) comprises epitaxial growth of at least one additional layer made of doped monocrystalline silicon carbide on the working layer, the additional layer forming all or part of the active layer;
   the production method comprises a step d′) of producing all or some of the electronic components on and/or in the active layer, step d′) being inserted between step d) and step e);
   step e) comprises mechanical detachment by propagating a crack through the temporary substrate following the application of a mechanical stress, the crack extending substantially parallel to the plane of the interface between the temporary substrate and the carrier layer;
   step e) comprises chemical detachment between the carrier layer and the temporary substrate by means of lateral chemical etching;
   step e) comprises chemical etching of all or part of the temporary substrate;
   step e) comprises detachment by thermally damaging the graphite of the temporary substrate;
   step c) comprises transferring a second working layer made of monocrystalline silicon carbide to the second carrier layer, directly or via a second intermediate layer, the transfer implementing bonding by molecular adhesion;
   step d) comprises forming a second active layer on the second working layer;
   step e) allows a second semiconductor structure to be formed, the structure including the second active layer, the second working layer and the second carrier layer; the temporary substrate, provided in step a), takes the form of a circular wafer and has a diameter that is 5% to 10% wider than a target diameter for the semiconductor structure;
   the temporary substrate, provided in step a), takes the form of a circular wafer and has a diameter that is slightly smaller than a target diameter for the semiconductor structure, such that the deposition of step b), also performed on a peripheral edge of the temporary substrate, allows the target diameter to be reached.

The present disclosure also relates to a composite structure comprising:
a temporary substrate made of graphite having a grain size of between 4 microns and 35 microns, a porosity of between 6 and 17%, and a coefficient of thermal expansion of between 4.10-6/° C. and 5.10-6/° ° C.,
a carrier layer made of polycrystalline silicon carbide having a thickness of between 10 microns and 200 microns, at least arranged on and in contact with a front face of the temporary substrate,
a working layer made of monocrystalline silicon carbide, arranged on the carrier layer.

According to other advantageous and non-limiting features of the present disclosure, taken individually or in any technically feasible combination:
the working layer has a thickness of between 100 nm and 1500 nm;
the temporary substrate has a thickness of between 100 microns and 2000 microns;
the temporary substrate has a thermal conductivity of between 70 W.m⁻¹.K⁻¹ and 130 W.m⁻¹.K⁻¹;
the temporary substrate and the carrier layer have a total thickness of between 110 microns and 500 microns, typically 350 microns +/−25 microns.

### BRIEF DESCRIPTION OF THE DRAWINGS

Other features and advantages of the present disclosure will become apparent from the following detailed description of example embodiments of the present disclosure, which is given with reference to the accompanying figures, in which:

FIG. 1 shows a semiconductor structure produced according to a production method in accordance with the present disclosure;

FIGS. 2A, 2B, 2C, 2D, 2D′, 2E, and 2F show steps of a production method in accordance with the present disclosure;

FIGS. 3A and 3B show steps of one particular embodiment of the production method in accordance with the present disclosure;

FIGS. 4A to 4C show a transfer step c) of the production method in accordance with the present disclosure.

In the figures, the same references may be used for elements of the same type.

The figures are schematic representations, which, for the sake of readability, are not to scale. In particular, the thicknesses of the layers along the z-axis are not to scale with respect to the lateral dimensions along the x- and y-axes; and the relative thicknesses of the layers with respect to one another have not necessarily been respected in the figures.

### DETAILED DESCRIPTION

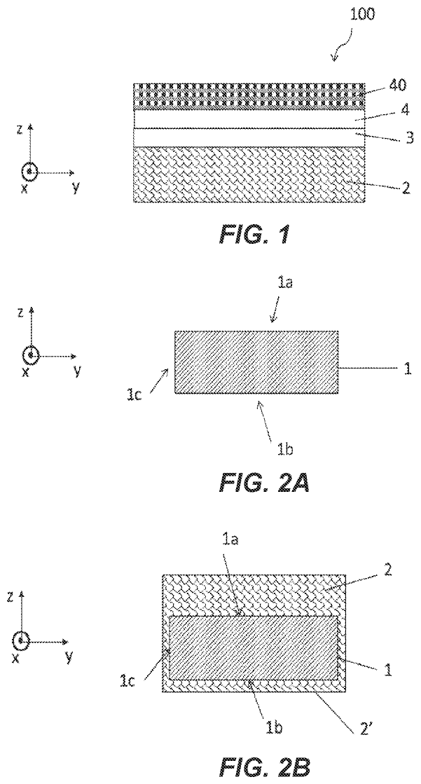

The present disclosure relates to a method for producing a semiconductor structure 100 (FIG. 1). What is meant by a semiconductor structure 100 is at least a stack of layers 4, 3, 2 intended to accommodate a plurality of microelectronic components; it is also understood to mean the stack of layers 4, 3, 2 with the electronic components 40, which originate from wafer-scale production on and/or in the active layer 4 held in the form of a wafer by a carrier layer 2, and which are ready to undergo steps of singularization before being packaged.

The production method is advantageously applicable to vertical microelectronic components, which require vertical electrical conduction through the carrier layer 2, which forms the mechanical carrier for the electronic components 40.

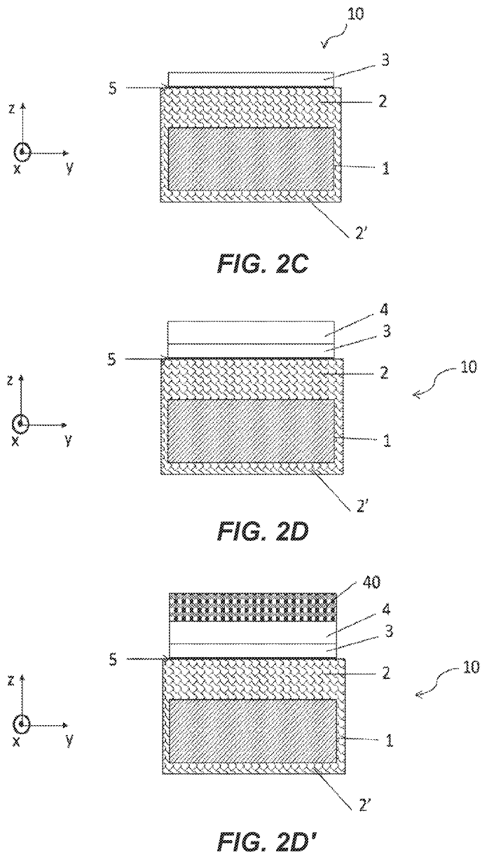

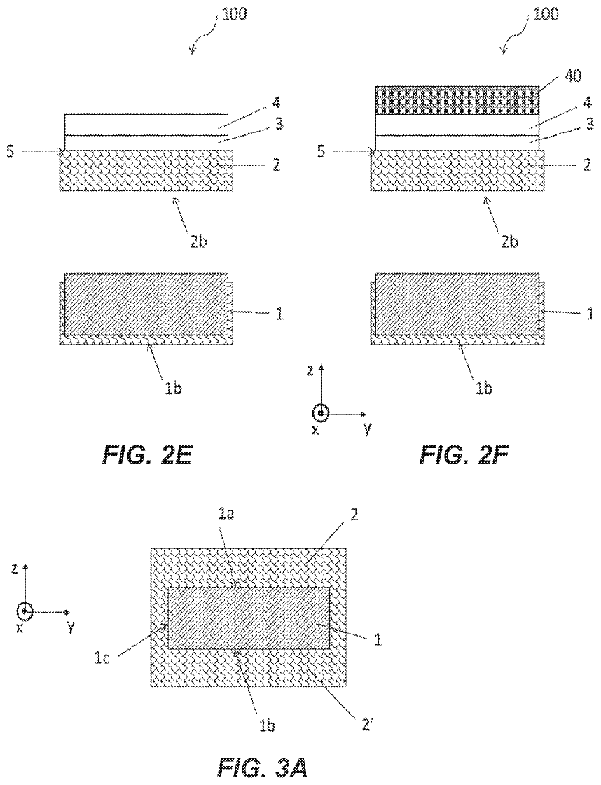

The production method first comprises a step a) of providing a temporary substrate 1 made of graphite having a front face 1a, a back face 1b and a peripheral edge 1c (FIG. 2A). The temporary substrate 1 made of graphite may be produced, for example, by way of plasma deposition, ion sputtering, cathodic arc deposition, laser evaporation of graphite, carbonization of a resin, etc.

The graphite of the temporary substrate 1 has an average grain size of between 4 microns and 35 microns, a porosity of between 6 and 17%, and a coefficient of thermal expansion of between 4.10⁻⁶/° C. and 5.10⁻⁶/° ° C.(between ambient temperature and 1000° C.). These characteristics are chosen, in particular, so as to provide an excellent seed for depositing a layer made of polycrystalline silicon carbide (p-SiC), called the carrier layer 2 hereinafter, and which will be described with reference to step b) of the method.

It should be noted that the average grain size corresponds to the arithmetic mean of the grain sizes that are greater than or equal to 100 nm. These grain sizes may be measured, for example, by way of scanning electron microscopy (SEM) or by way of electron backscatter diffraction (EBSD).

In particular, the range of average grain sizes is defined so that it is of the same order of magnitude as the average grain size expected for the carrier layer 2, in the plane of the faces 1a, 1b. The thermal conductivity of the carrier layer 2 is thus ensured, since the grains of the layer will not be too small; moreover, even if the grain size is made to grow when the carrier layer 2 is deposited, this is still within a controlled size range due to the defined range of average grain sizes of graphite, which limits the roughness on the free surface of the deposited carrier layer 2. The porosity range is also restricted so as to control the surface roughness of the carrier layer 2 after the subsequent deposition thereof (step b)). Typically, the surface roughness may be limited to less than 1 micron RMS, or even to less than 10 nm RMS, so as to reduce any smoothing treatments after the carrier layer 2 is deposited. Lastly, the coefficient of thermal expansion is defined so as to match the coefficient of thermal expansion of silicon carbide, in order to limit mechanical stresses in the structure during treatments (described later on in the method) involving high temperatures.

The temporary substrate 1 is compatible with temperatures that may range up to 1400° C. when the atmosphere is controlled, i.e., without oxygen; this is because, if exposed to air, graphite starts to burn within a low temperature range, typically 400° C.-600° C. Protected by a protective layer that completely encapsulates it, the temporary substrate 1 made of graphite is compatible with very high temperatures, even above 1400° C.

The production method next comprises a step b) of depositing, directly on the front face 1a of the temporary substrate 1, a carrier layer 2 made of polycrystalline silicon carbide (p-SiC) (FIG. 2B).

The deposition may be carried out using any known technique, in particular, chemical vapor deposition (CVD), at a temperature on the order of 1100° ° C. to 1400° C. For example, a thermal CVD technique such as atmospheric-pressure CVD (APCVD) or low-pressure CVD (LPCVD) may be cited, with the precursors being able to be selected from methylsilane, dimethyldichlorosilane or dichlorosilane+i-butane. A plasma-enhanced CVD (PECVD) technique may also be used, with, for example, silicon tetrachloride and methane as precursors; preferably, the frequency of the source used to generate the electric discharge creating the plasma is on the order of 3.3 MHz, and more generally between 10 kHz and 100 GHz.

Prior to deposition, conventional cleaning sequences may be applied to the temporary substrate 1 in order to remove all or some of the particulate, metal or organic contaminants potentially present on its free faces 1a, 1b.

The thickness of the carrier layer 2 made of p-SiC is between 10 microns and 200 microns. This thickness is chosen according to the thickness specifications expected for the semiconductor structure 100. Advantageously, the temporary substrate 1 and the carrier layer 2 have a total thickness of between 110 microns and 500 microns, typically 350 microns +/−25 microns. It is possible to cite the particular example of a temporary substrate 1 of 250 microns and of a carrier layer 2 of 100 microns, or of a temporary substrate 1 of 300 microns and of a carrier layer 2 of 50 microns.

The carrier layer 2 will act, in the semiconductor structure 100, as a mechanical substrate and will potentially have to ensure vertical electrical conduction. In order to guarantee the aforementioned electrical conduction property (low resistivity), the carrier layer 2 is advantageously n- or p-doped as required.

According to one advantageous embodiment, the deposition of step b) is also performed on the back face 1b of the temporary substrate 1 to form a second carrier layer 2′, and/or on the peripheral edge 1c of the temporary substrate 1.

The role of the second carrier layer 2′ (and of the p-SiC deposited on the peripheral edge 1c) may essentially be to protect the temporary substrate 1 made of graphite during the heat treatments at very high temperatures, which will come next in the method; the thickness of the second carrier layer 2′ and of the p-SiC deposited on the peripheral edge 1c (which are also called the protective layer hereinafter) will then be limited, on the order of a micron or of a few microns.

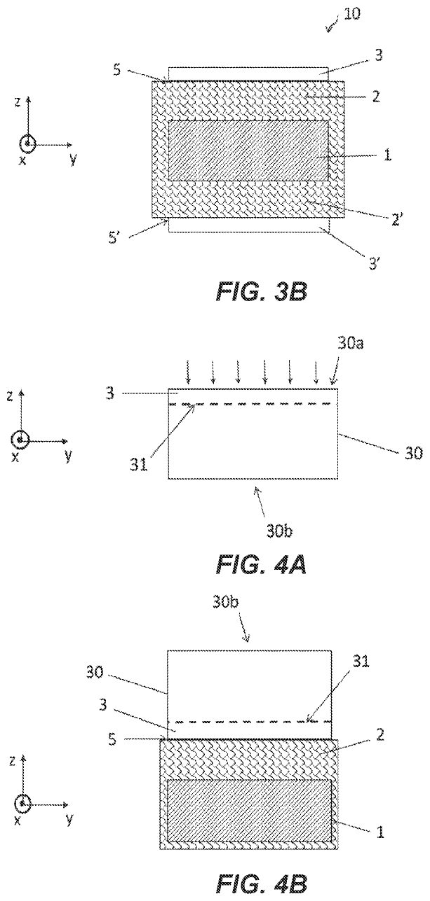

The second carrier layer 2′ may, alternatively, be deposited on the back face 1b of the temporary substrate 1 with a view to performing the next steps of the method on both faces 1a, 1b of the temporary substrate 1 (FIG. 3A). The second carrier layer 2′ then has a thickness of the same order of magnitude as the first carrier layer 2 arranged on the side of the front face 1a of the temporary substrate 1.

In general, after deposition of the carrier layer 2 (and potentially of the second carrier layer 2′), a surface treatment is carried out in order to improve the surface roughness of the carrier layer 2 and/or the quality of the edges of the structure, with a view to the next step of transferring the working layer 3.

Conventional chemical etching (wet or dry) and/or mechanical grinding and/or chemical-mechanical polishing techniques may be implemented to achieve a surface roughness of the p-SiC that is of the order of 0.5 nm RMS, preferably less than 0.3 nm RMS (roughness measurement using atomic force microscopy—AFM, on a 20 micron×20 micron scan, for example). The aforementioned characteristics of the graphite forming the temporary substrate 1 nevertheless allow the applied surface treatments to be limited.

According to a first variant, the temporary substrate 1, provided in step a), which typically takes the form of a circular wafer, has a diameter that is 5% to 10% wider than the target diameter for the final semiconductor structure 100. This may make it possible to limit edge issues during the deposition of step b) and to maximize the area occupied by future electronic components 40 on the semiconductor structure 100.

According to a second variant, the temporary substrate 1, provided in step a), has a diameter that is slightly smaller than the target diameter for the final semiconductor structure 100 (typically smaller by less than 5%), such that the deposition of step b), in this case performed on the peripheral edge of the temporary substrate 1, the target diameter to be reached.

Next, the production method according to the present disclosure comprises a step c) of transferring a working layer 3 made of monocrystalline silicon carbide (c-SiC) directly to the carrier layer 2 or via an intermediate layer, in order to form a composite structure 10 (FIG. 2C). The transfer implements bonding by molecular adhesion, and consequently a bonding interface 5. The intermediate layer may be formed on the side of the working layer 3 and/or on the side of the carrier layer 2, in order to promote the bonding.

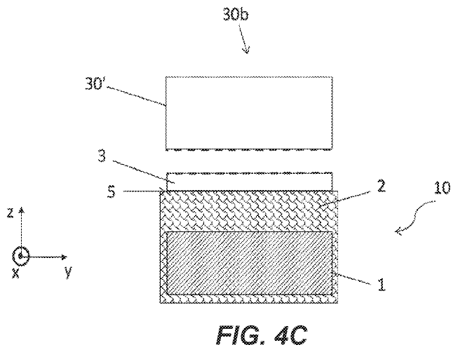

Advantageously, and as is known with reference to the Smart Cut™ method, the transfer step c) comprises, in succession:
introducing light species into a donor substrate 30 having a front face 30a and a rear face 30b and made of monocrystalline silicon carbide, in order to form a buried weakened plane 31, defining, with the front face 30a of the donor substrate 30, the working layer 3 (FIG. 4A),
joining the front face 30a of the donor substrate 30 to the carrier layer 2, directly or via an intermediate layer, by means of bonding by molecular adhesion, along a bonding interface 5 (FIG. 4B), and
separating, along the buried weakened plane 31, in order to transfer the working layer 3 to the carrier layer 2 (FIG. 4C).

The light species are preferably hydrogen, helium or a co-implantation of these two species, and are implanted into the donor substrate 30 at a determined depth, consistent with the thickness of the intended working layer 3 (FIG. 4A). These light species will form, around the determined depth, microcavities distributed as a thin layer parallel to the front face 30a of the donor substrate 30, that is parallel to the (x, y)-plane in the figures. This thin layer is referred to as the buried weakened plane 31, for the sake of simplicity.

The energy of implantation of the light species is selected so as to reach the determined depth. For example, hydrogen ions will be implanted at an energy of between 10 keV and 250 keV, and at a dose of between 5E16/cm2 and 1E17/cm2, to delimit a working layer 3 with a thickness of the order of 100 to 1500 nm. It should be noted that an additional layer could be deposited on the front face 30a of the donor substrate 30 prior to the ion implantation step. This additional layer may be composed of a material such as silicon oxide or silicon nitride, for example. It may be retained for the next step (and form all or part of the aforementioned intermediate layer), or it may be removed.

The donor substrate 30 is joined to the carrier layer 2 at the respective front faces thereof and forms a bonded assembly along the bonding interface 5 (FIG. 4B). As is well known per se, bonding by molecular adhesion does not require an adhesive material, as bonds are made at the atomic level between the joined surfaces. Several types of bonding by molecular adhesion exist, which differ, in particular, in the temperature, pressure, atmosphere conditions or treatments prior to bringing the surfaces into contact. Bonding at ambient temperature with or without prior plasma activation of the surfaces to be joined, atomic diffusion bonding (ADB), surface-activated bonding (SAB), etc., may be employed.

The joining step may comprise, before bringing the faces to be joined into contact, conventional cleaning, surface activation or other surface preparation sequences liable to promote the quality of the bonding interface 5 (low defectivity, good adhesion energy).

As already mentioned, the front face 30a of the donor substrate 30 and/or the free face of the carrier layer 2 may optionally comprise an intermediate layer, for example, a metal (tungsten, etc.) or doped semiconductor (silicon, etc.) layer in order to promote vertical electrical conduction, or an insulating layer (silicon oxide, silicon nitride, etc.) for applications not requiring vertical electrical conduction. The intermediate layer is liable to promote bonding by molecular adhesion, in particular, by erasing residual roughness or surface defects present on the faces to be joined. It may undergo planarizing or smoothing treatments in order to achieve a roughness of less than 1 nm RMS, or even less than 0.5 nm RMS, which is favorable for bonding.

Separation along the buried weakened plane 31 usually occurs by applying a heat treatment at a temperature of between 800° C. and 1,200° ° C.(FIG. 4C). Such a heat treatment causes cavities and microcracks to develop in the buried weakened plane 31, and their pressurization by the light species present in gaseous form, until a fracture propagates along the weakened plane 31. Alternatively, or jointly, a mechanical stress may be applied to the bonded assembly, and, in particular, to the buried weakened plane 31, so as to propagate or assist the mechanical propagation of the fracture leading to the separation. On completion of this separation, the composite structure 10 comprising the temporary substrate 1 made of graphite, the carrier layer 2 made of p-SiC and the transferred working layer 3 made of c-SiC is obtained, on the one hand, and the rest 30′ of the donor substrate is obtained, on the other hand. The working layer 3 is typically between 100 nm and 1500 nm thick. The level and type of doping of the working layer 3 is defined by the choice of the properties of the donor substrate 30 or may be adjusted later on via the known techniques for doping semiconductor layers.

The free surface of the working layer 3 is usually rough after separation: for example, its roughness is between 5 nm and 100 nm RMS (AFM, 20 microns×20 microns scan). Cleaning and/or smoothing steps may be applied in order to restore a good surface finish (typically, roughness of less than a few angstroms RMS on a 20 micron×20 micron AFM scan).

Alternatively, the free surface of the working layer 3 may remain rough, as separated, when the following step of the method tolerates this roughness.

If the edges 1c and the back face 1b of the temporary substrate 1 are not covered by a protective layer, the separation heat treatment is carried out under a controlled atmosphere without oxygen.

Advantageously, a protective layer is deposited before this heat treatment, in order to relax the atmosphere conditions for the treatment. The protective layer may be formed of p-SiC as mentioned with reference to the particular embodiment involving the second carrier layer 2′, or made of amorphous SiC.

In the particular embodiment implementing a second carrier layer 2′, step c) may also comprise transferring a second working layer 3′ made of c-SiC to the second carrier layer 2′, directly or via a second intermediate layer, involving a second bonding interface 5′ (FIG. 3B).

The production method according to the present disclosure then comprises a step d) of forming an active layer 4 on the working layer 3 (FIG. 2D).

Advantageously, the active layer 4 is produced by epitaxially growing at least one additional layer made of doped monocrystalline silicon carbide on the working layer 3. This epitaxial growth occurs in the conventional temperature range, namely between 1500° C. and 1900° C., and forms a layer that is of the order of 1 micron to several tens of microns thick, depending on the intended electronic components.

The presence of a protective layer on the edges 1c and the back face 1b of the temporary substrate 1 made of graphite, in the composite structure 10, is required to prevent the graphite from being damaged by the aforementioned treatments at very high temperatures. As mentioned above, this protective layer may, for example, consist of a layer made of polycrystalline silicon carbide (second carrier layer 2′) or an amorphous layer.

The production method according to the present disclosure may further comprise a step d′) of producing all or some of the electronic components 40 on and/or in the active layer 4 (FIG. 2D′). The electronic components 40 may, for example, consist of transistors or other high-voltage and/or high-frequency components.

In order for them to be produced on and/or in the active layer 4, conventional steps of cleaning, deposition, lithography, implantation, etching, planarization and heat treatment are carried out. In particular, among the mentioned heat treatments, some are intended to activate dopants locally introduced into the active layer 4 (or the working layer 3), and are typically carried out at a temperature above or equal to 1600° C.

It should be noted that in the particular embodiment implementing a second carrier layer 2′ on the back face of the temporary substrate 1, step d) may also comprise the formation of a second active layer on the second working layer 3′; and step d′) may comprise producing all or some second electronic components on and/or in the second active layer.

Lastly, the production method according to the present disclosure comprises a step e) of removing the temporary substrate 1 to form the semiconductor structure 100, the structure including the active layer 4, the working layer 3 and the carrier layer 2 (FIG. 2E), and potentially the electronic components 40 (FIG. 2F), if a step d′ has been carried out.

Several variants may be implemented for this step: some variants (first and second variants described below) are based on detaching the temporary substrate 1 and may therefore potentially include the recycling thereof for a new use; other variants (third and fourth variants) involve the partial or total elimination of the temporary substrate 1.

According to a first variant, step e) comprises mechanical detachment by propagating a crack through the temporary substrate 1 following the application of a mechanical stress, the crack extending substantially parallel to the plane of the interface between the temporary substrate 1 and the carrier layer 2, 2′. For example, inserting a beveled tool opposite or close to the interface allows an opening to be initiated and propagated at this interface or in the graphite of the temporary substrate 1, until there is complete separation between the semiconductor structure 100 and the temporary substrate 1. Advantageously, the protective layer present on the edges 1c of the temporary substrate 1 is removed, in order to promote the initiation of the crack in the graphite.

According to a second variant, step e) comprises chemical removal between the carrier layer 2, 2′ and the temporary substrate 1, by means of lateral chemical etching. The protective layer located on the edges 1c of the temporary substrate 1 in the composite structure 10 must be removed chemically or mechanically, in order to allow access to the graphite. The lateral chemical etching may, in particular, implement a solution based on nitric acid and/or sulfuric acid, for example, a solution of concentrated sulfuric acid and potassium dichromate or a solution of sulfuric acid, nitric acid and potassium chlorate. Chemical etching implementing an alkaline solution (such as potassium hydroxide (KOH) or sodium hydroxide (NaOH)) may also be applied.

Of course, careful attention will be given to the protection of the free face and the edges of the active layer 4 and the electronic components 40 if they are present, and/or to limiting the contact time with the etching solution, in order to avoid damaging them during this chemical removal.

According to a third variant, step e) comprises chemical etching of all or part of the temporary substrate 1. As mentioned above, the protective layer on the edges 1c and on the back face 1b (second carrier layer 2′) of the temporary substrate 1 of the composite structure 10 will have to be removed to give access to the graphite. Mechanical removal could typically be performed, for example, by grinding the edges and grinding the back face, or chemical removal, depending on the nature of the protective layer. The chemical etching of the temporary substrate 1 could, for example, implement one of the solutions given above for the second variant, taking care to protect the active layer 4 and potentially the electronic components 40.

According to a fourth variant, step e) comprises detachment by thermally damaging the graphite forming the temporary substrate 1. Here again, the protective layer present at least on the edges of the temporary substrate 1 has to be removed. When there is no second working layer 3′ on the back face of the composite structure 10, the protective layer could also be removed from this face.

Detachment by thermal damage may occur at a temperature of between 600° C. and 1000° C., in the presence of oxygen: the graphite of the temporary substrate 1 is then burnt and crumbles so as to leave only the semiconductor structure 100 intact.

Of course, in the case whereby the electronic components 40 have been produced in step d′, this detachment variant may only be applied if the electronic components 40 are compatible with the applied temperature.

It should be noted that the aforementioned variants may optionally be combined with one another in any technically feasible manner.

Irrespective of the variant that is implemented, the removal of the temporary substrate 1 may leave residues on the back face 2b of the carrier layer 2. These residues are then eliminated by mechanical grinding, by chemical-mechanical polishing, by chemical etching and/or by thermal damage. Chemical-mechanical polishing or chemical etching techniques may also be implemented to reduce the roughness of the back face 2b of the carrier layer 2, if need be.

In the particular embodiment mentioned above, for which a second carrier layer 2′, a second working layer 3′ and a second active layer are arranged on the back face 1b of the temporary substrate 1, step e) of removing the temporary substrate 1 also allows a second semiconductor structure to be formed, this structure including the second active layer (and potentially electronic components), the second working layer 3′ and the second carrier layer 2′.

If the semiconductor structure 100 must be handled during and after the removal of the temporary substrate 1, and its total thickness is insufficient for it to be mechanically held in this handling operation, it is possible to contemplate using a detachable handle: the handle is arranged on the active layer 4 and is temporarily secured thereto, in order to carry out handling until the singularization step, for example.

The semiconductor structure 100 that is obtained on completion of the production method according to the present disclosure comprises an active layer 4, potentially finalized with electronic components 40, and arranged on a carrier layer 2 with the thickness that is intended for the application. No mechanical thinning involving significant material loss is required. The carrier layer 2 is made of good-quality p-SiC (as it is deposited at relatively high temperatures), but it is low cost in comparison with a bulk substrate of monocrystalline or polycrystalline SiC, which would have had to be significantly thinned before singularization of the components. The temporary substrate 1 made of graphite is advantageously recovered for recycling. Even if it is not reused, since graphite is a low-cost material, the production method according to the present disclosure remains economically advantageous with respect to a solution with a bulk substrate made of SiC. The choice of the physical characteristics of the temporary substrate 1 made of graphite (grain size, porosity, coefficient of thermal expansion) ensures the formation of a carrier layer 2 allowing a robust and quality composite structure 10 to be obtained, and allowing a reliable and high-performance semiconductor structure 100 to be obtained. The performance of the electronic components 40 arises, in particular, from the fact that the composite structure 10 allows very high-temperature treatments for forming the active layer 4.

The present disclosure also relates to a composite structure 10, described above with reference to the production method, and corresponding to an intermediate structure obtained in the method (FIG. 2C, 2D, 2D′, 3B).

The composite structure 10 comprises:
a temporary substrate 1 made of graphite having a grain size of between 4 microns and 35 microns, a porosity of between 6 and 17%, and a coefficient of thermal expansion of between 4.10⁻⁶/° C. and 5.10⁻⁶/° C.,
a carrier layer 2 made of polycrystalline silicon carbide having a thickness of between 10 microns and 200 microns, at least arranged on and in contact with a front face 1a of the temporary substrate 1, and
a working layer 3 made of monocrystalline silicon carbide, arranged directly on the carrier layer 2 or via an intermediate layer.

Preferably, the thickness of the working layer 3 is between 100 nm and 1500 nm. The thickness of the temporary substrate 1 is between 100 microns and 2000 microns.

For applications for vertical microelectronic components, the carrier layer 2 advantageously exhibits good electrical conductivity, i.e., between 0.015 and 0.03 ohm.cm, high thermal conductivity, i.e., higher than or equal to 200 W.m⁻¹.K⁻¹, and a coefficient of thermal expansion that is similar to that of the working layer 3, i.e., typically between 3.8X10-6/° C. and 4.2X10⁻⁶/° C. at ambient temperature.

The temporary substrate 1 may advantageously have a thermal conductivity of between 70 W.m⁻¹.K⁻¹ and 130 W.m⁻¹.K⁻¹, so as to provide a homogeneous temperature on the temporary substrate 1 during the very high-temperature heat treatment steps of the production method. In particular, this improves the uniformity of the deposited layers and the reproducibility of the physical properties of the layers and components produced.

Lastly, as has been described with reference to the production method according to the present disclosure, the composite structure 10 may be “double-sided,” i.e., it may comprise:
a second carrier layer 2′ made of polycrystalline silicon carbide having a thickness of between 10 microns and 200 microns, arranged on the temporary substrate 1,
a second working layer 3′ made of monocrystalline silicon carbide, arranged on the second carrier layer 2′ (FIG. 3B).

Such a composite structure 10 allows two active layers 4 to be formed on the first and the second working layer 3, 3′, respectively, and, on completion of the production method according to the present disclosure, it allows two semiconductor structures 100 to be obtained from a single temporary substrate 1.

Of course, the present disclosure is not limited to the described embodiments and examples, and changes may be made thereto without departing from the scope of the invention as defined by the claims.

1. A method for producing a semiconductor structure, comprising:
providing a temporary substrate of graphite having a grain size of between 4 microns and 35 microns, a porosity of between 6 and 17%, and a coefficient of thermal expansion of between 4×10⁻⁶/° C. and 5×10⁻⁶/° C.;
depositing, directly on a front face of the temporary substrate, a carrier layer of polycrystalline silicon carbide having a thickness between 10 microns and 200 microns;
transferring a working layer of monocrystalline silicon carbide on the carrier layer, directly or via an intermediate layer, to form a composite structure, the transfer implementing bonding by molecular, adhesion;
forming an active layer on the working layer; and
removing the temporary substrate to form the semiconductor structure, the semiconductor structure including the active layer, the working layer and the carrier layer.

2. The method of claim 1, wherein depositing of the carrier layer is also performed:
on a back face of the temporary substrate to form a second carrier layer; and/or
on a peripheral edge of the temporary substrate.

3. The method of claim 1, wherein the transferring of the working layer comprises:
introducing light species into a donor substrate of monocrystalline silicon carbide to form a buried weakened plane defining, with a front face of the donor substrate, the working layer;
joining the front face of the donor substrate to the carrier layer, directly or via an intermediate layer, by way of bonding by molecular adhesion; and
separating, along the buried weakened plane, to transfer the working layer to the carrier layer.

4. The method of claim 3, wherein the front face of the donor substrate is joined to the carrier layer via the intermediate layer, and the intermediate layer comprises a conductive material or a semiconductor material.

5. The method of claim 1, wherein the forming of the active layer comprises epitaxial growth of at least one additional layer of doped monocrystalline silicon carbide on the working layer, the additional layer forming all or part of the active layer.

6. The method of claim 1, further comprising producing electronic components on and/or in the active layer after forming the active layer and before removing the temporary substrate.

7. The method of claim 1, wherein:
the removing of the temporary substrate comprises mechanical detachment by propagating a crack through the temporary substrate following application of a mechanical stress, the crack extending substantially parallel to a plane of the interface between the temporary substrate and the carrier layer; and/or
the removing of the temporary substrate comprises chemical detachment between the carrier layer and the temporary substrate by way of lateral chemical etching; and/or
the removing of the temporary substrate comprises chemical etching of at least a portion of the temporary substrate; and/or
the removing of the temporary substrate comprises detachment by thermally damaging the graphite of the temporary substrate.

8. The method of claim 2, wherein:
the transferring of the working layer comprises transferring a second working layer of monocrystalline silicon carbide to the second carrier layer, directly or via a second intermediate layer, the transfer implementing bonding by molecular adhesion;
the forming of the active layer comprises forming a second active layer on the second working layer; and
the removing of the temporary substrate results in formation of a second structure semiconductor structure, the second semiconductor structure including the second active layer, the second working layer and the second carrier layer.

9. The method of claim 1, wherein the temporary substrate is in the form of a circular wafer and has a diameter that is 5% to 10% wider than a target diameter for the semiconductor structure.

10. The method of claim 1, wherein the temporary substrate is in the form of a circular wafer and has a diameter that is slightly smaller than a target diameter for the semiconductor structure, and wherein the depositing of the carrier layer is also performed on a peripheral edge of the temporary substrate, to provide the temporary substrate with the target diameter.

11. A composite structure, comprising:
a temporary substrate of graphite having a grain size of between 4 microns and 35 microns, a porosity of between 6 and 17%, and a coefficient of thermal expansion of between 4×10⁻⁶/° C. and 5×10⁻⁶/° C.;
a carrier layer of polycrystalline silicon carbide having a thickness of between 10 microns and 200 microns, at least arranged on and in contact with a front face of the temporary substrate; and
a working layer made of monocrystalline silicon carbide, arranged on the carrier layer.

12. The composite structure of claim 11, wherein the working layer has a thickness of between 100 nm and 1500 nm.

13. The composite structure of claim 11, wherein the temporary substrate has a thickness of between 100 microns and 2000 microns.

14. The composite structure of claim 11, wherein the temporary substrate has a thermal conductivity of between 70 W.m⁻¹.K⁻¹ and 130 W.m⁻¹.K⁻¹.

15. The method of claim 4, wherein the intermediate layer comprises tungsten, silicon, or silicon carbide.

16. The method of claim 2, wherein the transferring of the working layer comprises:
introducing light species into a donor substrate of monocrystalline silicon carbide to form a buried weakened plane defining, with a front face of the donor substrate, the working layer;
joining the front face of the donor substrate to the carrier layer, directly or via an intermediate layer, by way of bonding by molecular adhesion; and
separating, along the buried weakened plane, to transfer the working layer to the carrier layer.

17. The method of claim 16, wherein the forming of the active layer comprises epitaxial growth of at least one additional layer of doped monocrystalline silicon carbide on the working layer, the additional layer forming all or part of the active layer.

18. The method of claim 17, further comprising producing electronic components on and/or in the active layer after forming the active layer and before removing the temporary substrate.

19. The method of claim 18, wherein the temporary substrate is in the form of a circular wafer and has a diameter that is 5% to 10% wider than a target diameter for the semiconductor structure.

20. The method of claim 18, wherein the temporary substrate is in the form of a circular wafer and has a diameter that is slightly smaller than a target diameter for the semiconductor structure, and wherein the depositing of the carrier layer is also performed on a peripheral edge of the temporary substrate, to provide the temporary substrate with the target diameter.
